(19) United States
(12) Patent Application Publication
(10) Pub. No.: US 2010/0133544 A1
(43) Pub. Date: Jun. 3, 2010

(54) THIN FILM TRANSISTOR AND FABRICATING METHOD THEREOF

(75) Inventors: Ta-Chuan Liao, Taichung City (TW); Huang-Chung Cheng, Hsinchu City (TW); Ya-Hsiang Tai, Hsinchu City (TW); Szu-Fen Chen, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/366,657

(22) Filed: Feb. 6, 2009

(30) Foreign Application Priority Data
Nov. 28, 2008 (TW) 97146572

(51) Int. Cl. H01L 29/786; H01L 21/336

(52) U.S. Cl. 257/66; 438/164; 257/E29.296; 257/E21.412

(57) ABSTRACT

A thin film transistor (TFT) includes a poly-silicon island, a gate insulating layer, a gate stack layer, and a dielectric layer. The poly-silicon island includes a source region and a drain region. The gate insulating layer covers the poly-silicon island. The gate stack layer is disposed on the gate insulating layer and includes a first conductive layer and a second conductive layer. A length of the first conductive layer is less than a length of the second conductive layer. The dielectric layer covers the gate insulating layer and the gate stack layer, and therefore a number of cavities are formed between the second conductive layer and the gate insulating layer.

### CROSS-REFERENCE TO RELATED APPLICATION

This application claims the priority benefit of Taiwan application serial no. 97146572, filed Nov. 28, 2008. The entirety of the above-mentioned patent application is hereby incorporated by reference herein and made a part of specification.

### BACKGROUND OF THE INVENTION

1. Field of the Invention

The present invention relates to a thin film transistor (TFT) and a fabricating method thereof. More particularly, the present invention relates to a poly-silicon TFT and a fabricating method thereof.

2. Description of Related Art

Most devices require switches for driving the same. For instance, an active driving display device is often triggered by using a TFT. The TFT can be categorized into an amorphous silicon (a-Si) TFT and a poly-silicon TFT. By virtue of low power consumption and great electron mobility in comparison with the a-Si TFT, the poly-silicon TFT has little by little drawn more attention in the industry.

With rapid advancement of integrated circuit (IC) industry, devices are required to be downsized in the process of semiconductor fabrication, so as to improve driving capacity and increase integration of the devices. FIG. 1 is a schematic cross-sectional view illustrating a conventional poly-silicon TFT. The poly-silicon TFT 100 includes a poly-silicon island 120, a gate insulating layer 130, a gate layer 140, and a dielectric layer 150. The poly-silicon island 120 has a source region 120S, a drain region 120D, and a channel region 120C. Referring to FIG. 1, the poly-silicon island 120, the gate insulating layer 130, the gate layer 140, and the dielectric layer 150 are sequentially formed on a substrate 110.

When the dimension of the poly-silicon TFT 100 decreases, a length L″ of the channel region 120C in the poly-silicon TFT 100 is reduced as well. Nonetheless, when the length L″ of the channel region 120C is reduced to a certain degree, electric energy generated in a junction between the channel region 120C and the drain region 120D is increased in the process of driving the poly-silicon TFT 100, thereby deteriorating leakage current. Said phenomenon is referred to as a short channel effect and gives rise to electrical degradation of the poly-silicon TFT 100.

In general, the problem of the short channel effect occurring in the poly-silicon TFT 100 is often resolved by way of a lightly doped drain (LDD) or an offset gate. However, the formation of the LDD necessitates additional implementation of an ion implantation process. Besides, the fabrication of the offset gate requires an additional photomask process and thus results in misalignment.

### SUMMARY OF THE INVENTION

The present invention is directed to a TFT having a relatively low leakage current.

The present invention is further directed to a fabricating method of a TFT. By applying the fabricating method, the aforesaid TFT can be formed through performing simple manufacturing processes.

In the present invention, a TFT including a poly-silicon island, a gate insulating layer, a gate stack layer, and a dielectric layer is provided. The poly-silicon island includes a source region and a drain region. The gate insulating layer covers the poly-silicon island. The gate stack layer is disposed on the gate insulating layer and includes a first conductive layer and a second conductive layer. A length of the first conductive layer is less than a length of the second conductive layer. The dielectric layer covers the gate insulating layer and the gate stack layer, and therefore a plurality of cavities are formed between the second conductive layer and the gate insulating layer.

In the present invention, a fabricating method of a TFT is also provided. In the fabricating method, a poly-silicon island and a gate insulating layer are sequentially formed on a substrate. A gate stack layer is then formed on the gate insulating layer. The gate stack layer includes a first conductive layer and a second conductive layer. Next, an etching process is performed. The etching process has an etching selectivity with respect to the first conductive layer and the second conductive layer, such that a length of the first conductive layer is less than a length of the second conductive layer, and a plurality of recesses are formed between the second conductive layer and the gate insulating layer. Thereafter, a source region and a drain region are formed in the poly-silicon island. After that, a dielectric layer covering the second conductive layer is formed on the gate insulating layer. The recesses are not filled with the dielectric layer, and therefore a plurality of cavities are formed between the second conductive layer and the gate insulating layer.

According to an embodiment of the present invention, an etching rate of the first conductive layer is at least twice an etching rate of the second conductive layer.

According to an embodiment of the present invention, the length of the second conductive layer is substantially less than 3 microns.

According to an embodiment of the present invention, a ratio of a distance between an edge of the first conductive layer and an edge of the second conductive layer to the length of the second conductive layer is substantially less than 0.2.

According to an embodiment of the present invention, a method of forming the dielectric layer includes performing a plasma enhanced chemical vapor deposition (PECVD) process or a sputtering process.

According to an embodiment of the present invention, a dielectric constant in the cavities is substantially equal to 1.

According to an embodiment of the present invention, the etching process has a high etching selectivity ratio. According to an embodiment of the present invention, the etching process having the high etching selectivity ratio is performed with use of a wet etching solution. According to another embodiment of the present invention, the wet etching solution is phosphoric acid (H₃PO₄), oxalic acid ((COOH)₂.2H₂O), or hydrogen peroxide (H₂O₂).

According to an embodiment of the present invention, a material of the first conductive layer is aluminum (Al), indium tin oxide (ITO), or poly-germanium.

According to an embodiment of the present invention, a material of the second conductive layer is molybdenum (Mo) or poly-silicon.

The gate stack layer and the cavities in the TFT of the present invention result in reduction of leakage current in the TFT, and thereby the problem of the short channel effect can be resolved. In addition, the fabricating method of the TFT in the present invention can be applied to form the aforesaid TFT through simplified manufacturing processes. As such, the fabricating method of the TFT in the present invention is conducive to lowering the manufacturing costs and improving manufacturing efficiency.

In order to make the aforementioned and other features and advantages of the present invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic cross-sectional view illustrating a conventional poly-silicon TFT.

FIGS. 2A˜2E are schematic cross-sectional flowcharts illustrating processes of fabricating a TFT according to an embodiment of the present invention.

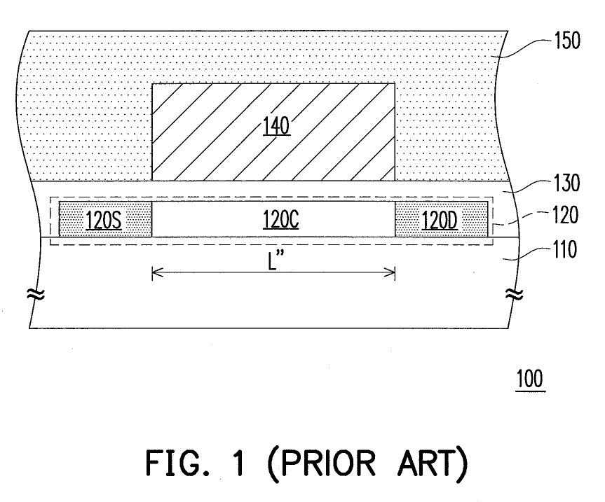

### DESCRIPTION OF EMBODIMENTS

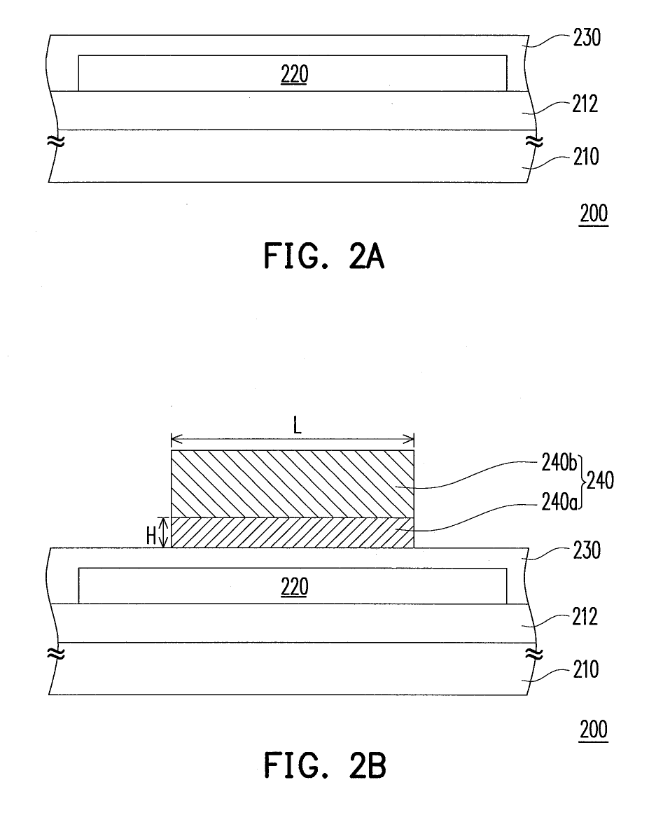

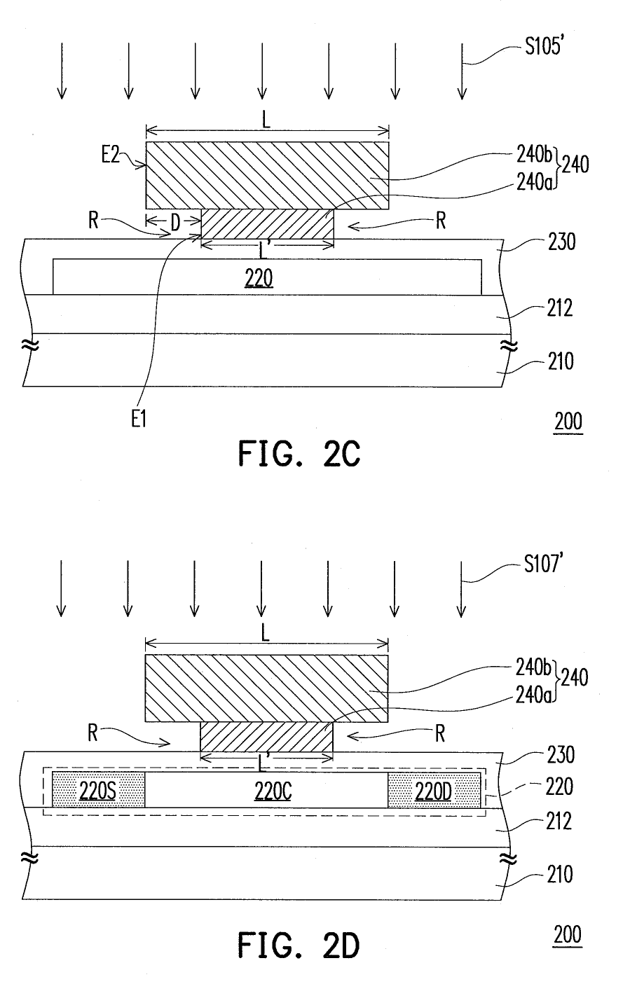

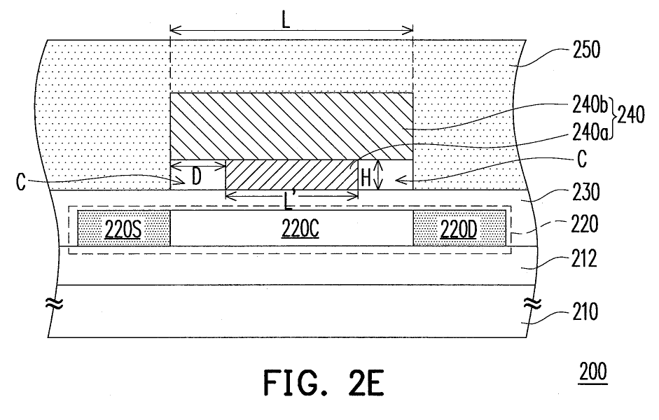

FIGS. 2A˜2E are schematic cross-sectional flowcharts illustrating processes of fabricating a TFT according to an embodiment of the present invention. A fabricating method of a TFT in the present embodiment is described hereinafter. Please refer to FIGS. 2A˜2E sequentially. By applying the fabricating method, the TFT discussed in the present embodiment can be formed.

Referring to FIG. 2A, first, a poly-silicon island 220 and a gate insulating layer 230 are formed on a substrate 210 in order. In the present embodiment, the substrate 210 is made of glass or silicon, for example. Besides, prior to the formation of the poly-silicon island 220, a buffer layer 212 can be selectively formed on the substrate 210.

As indicated in FIG. 2B, a gate stack layer 240 is then formed on the gate insulating layer 230. The gate stack layer 240 includes a first conductive layer 240a and a second conductive layer 240b. In a method of forming the gate stack layer 240, for example, a material of the first conductive layer 240a and a material of the second conductive layer 240b are sequentially formed on the gate insulating layer 230 at first. A photomask process is then performed to define the first conductive layer 240a and the second conductive layer 240b.

It should be mentioned that a length L of the first conductive layer 240a in the present embodiment is substantially equal to a length L of the second conductive layer 240b, and the length L is substantially less than 3 microns. Additionally, the first conductive layer 240a has a height H, for example.

In the present embodiment, the first conductive layer 240a is, for example, made of Al, ITO, or poly-germanium, and the second conductive layer 240b is, for example, made of Mo or poly-silicon. Certainly, in other embodiments, the first conductive layer 240a and the second conductive layer 240b can be made of other materials. The aforesaid materials of the first conductive layer 240a and the second conductive layer 240b should not be construed as a limitation to the present invention.

Referring to FIG. 2C, an etching process S105′ is then performed. The etching process S105′ has an etching selectivity with respect to the first conductive layer 240a and the second conductive layer 240b, such that a length of the first conductive layer 240a is less than the length of the second conductive layer 240b, and a plurality of recesses R are formed between the second conductive layer 240b and the gate insulating layer 230.

According to the present embodiment, the etching process S105′ has a high etching selectivity ratio. Besides, the etching process S105′ having the high etching selectivity ratio is performed with use of a wet etching solution, for example, and the wet etching solution can be composed of H₃PO₄, (COOH)₂.2H₂O, H₂O₂, or the like. Nevertheless, the wet etching solution can also be composed of other materials in other embodiments. The aforesaid materials of the wet etching solution should not be construed as a limitation to the present invention.

To be more specific, the wet etching solution employed in the etching process S105′ of the present embodiment has a higher etching selectivity ratio with respect to the material of the first conductive layer 240a than the material of the second conductive layer 240b. Here, an etching rate of the first conductive layer 240a is at least twice an etching rate of the second conductive layer 240b. Therefore, in the present embodiment, after implementation of the etching process S105′ having the high etching selectivity ratio, the second conductive layer 240b substantially has the length L. The first conductive layer 240a is partially removed, and the remaining first conductive layer 240a on the gate insulating layer 230 has a length L′ as indicated in FIG. 2C. Here, the first conductive layer 240a and the second conductive layer 240b of the gate stack layer 240 appear to have a T-shaped structure.

For instance, in the present embodiment, the first conductive layer 240a is made of Al, the second conductive layer 240b is made of Mo, and the wet etching solution is H₃PO₄. When the etching process S105′ is performed with use of H₃PO₄ as the wet etching solution in the present embodiment, reactions between H₃PO₄ and Al bring about partial removal of Al because Al has a high etching selectivity ratio with respect to Mo. Besides, Mo can be protected from being etched by H₃PO₄.

However, in other embodiments, the materials of the first conductive layer 240a, the second conductive layer 240b, and the wet etching solution can also be ITO, Mo, and (COOH)₂.2H₂O, respectively. Alternatively, the materials of the first conductive layer 240a, the second conductive layer 240b, and the wet etching solution can be poly-germanium, poly-silicon, and H₂O₂, respectively. It is for sure the first conductive layer 240a, the second conductive layer 240b, and the wet etching solution are likely to be made of other appropriate materials alone or in combination, and no further descriptions in this regard are provided herein.

In the present embodiment, after the aforesaid etching process S105′ is carried out, it should be noted that the first conductive layer 240a and the second conductive layer 240b substantially have the length L′ and the length L, respectively. At this time, a ratio of a distance D between an edge E1 of the first conductive layer 240a and an edge E2 of the second conductive layer 240b to the length L of the second conductive layer 240b is less than 0.2.

Please refer to FIG. 2D. A source region 220S and a drain region 220D are then formed in the poly-silicon island 220. The source region 220S and the drain region 220D are formed by performing an ion implantation process S107′ on the poly-silicon island 220, for example. Particularly, a channel region 220C is formed between the source region 220S and the drain region 220D in the poly-silicon island 220 of the present embodiment. The channel region 220C can serve as an electric channel between the source region 220S and the drain region 220D.

It should be mentioned that the length L of the channel region 220C is substantially equal to the length L of the second conductive layer 240b in the present embodiment. That is to say, the length L of the channel region 220C is substantially less than 3 microns.

Referring to FIG. 2E, a dielectric layer 250 is then formed on the gate insulating layer 230, and the dielectric layer 250 covers the second conductive layer 240b. The recesses R are not filled with the dielectric layer 250, and therefore a plurality of cavities C are formed between the second conductive layer 240b and the gate insulating layer 230.

According to the present embodiment, a method of forming the dielectric layer 250 includes performing a PECVD process or a sputtering process. For instance, during implementation of the PECVD process or the sputtering process, the dielectric layer 250 is formed in a vertically isotropic manner under a vacuum environment. Hence, the dielectric layer 250 is not formed in the recesses R. After the second conductive layer 240b and the gate insulating layer 230 are covered by the dielectric layer 250, the recesses R depicted in FIG. 2D become the cavities C illustrated in FIG 2E. Here, the cavities C are vacuum cavities. Namely, a dielectric constant in the cavities C is substantially equal to 1. Up to here, the fabrication of the TFT 200 is roughly completed.

As indicated in FIG. 2E, the TFT 200 of the present embodiment includes the poly-silicon island 220, the gate insulating layer 230, the gate stack layer 240, and the dielectric layer 250.

The poly-silicon island 220 includes the source region 220S and the drain region 220D. According to the present embodiment, the length L of the channel region 220C between the source region 220S and the drain region 220D in the poly-silicon island 220 is substantially less than 3 microns.

The gate insulating layer 230 covers the poly-silicon island 220.

The gate stack layer 240 is disposed on the gate insulating layer 230 and includes the first conductive layer 240a and the second conductive layer 240b. The length L′ of the first conductive layer 240a is less than the length L of the second conductive layer 240b. In the present embodiment, the length L of the second conductive layer 240b is substantially less than 3 microns, and the first conductive layer 240a has the height H, for example.

The dielectric layer 250 covers the gate insulating layer 230 and the gate stack layer 240, and therefore the plurality of cavities C are formed between the second conductive layer 240b and the gate insulating layer 230. In other words, the cavities C of the present embodiment can be surrounded by the gate insulating layer 230, the first conductive layer 240a, the second conductive layer 240b, and the dielectric layer 250.

It can be deduced from the above descriptions that the cavities C of the present embodiment are close to the source region 220S and the drain region 220D, such that the gate stack layer 240 appears to have the T-shaped structure. Besides, the dielectric constant in the cavities C is substantially equal to 1, and the gate insulating layer 230 has a relatively high dielectric constant. Accordingly, due to the formation of the cavities C and the gate insulating layer 230, an equivalent dielectric constant near the source region 220S and the drain region 220D ranges from 1 to the value of the dielectric constant of the gate insulating layer 230. Namely, the dielectric constant near the source region 220S and the drain region 220D is less than the dielectric constant of the gate insulating layer 230. Thereby, a vertical electric field generated at a junction of the drain region 220D is decreased, and leakage current of the TFT 200 is further reduced.

Note that the first conductive layer 240a has the height H, for example, and the height of the cavities C is substantially equal to the height H of the first conductive layer 240a. As such, in order to improve the driving capability of the TFT 200, the height H of the first conductive layer 240a can be adjusted, such that the height H of the cavities C can be reduced, and the driving current of the TFT 200 can then be increased.

On the other hand, when the cavities C has a relatively great height H because of adjustment of the height H of the first conductive layer 240a, the vertical electric field generated at the junction of the drain region 220D is decreased, thereby giving rise to a reduced leakage current of the TFT 200. Besides, the length L of the channel region 220C is substantially less than 3 microns in the present embodiment. That is, the problem of the short channel effect occurring in the TFT 200 can be resolved as well.

In light of the foregoing, the TFT of the present invention can be formed by applying the fabricating method of the TFT described herein. The TFT can have a T-shaped gate stack layer for reducing the leakage current of the TFT. According to the fabricating method of the TFT in the present invention, the formation of the dielectric layer relies on the etching process which has a high etching selectivity ratio and is performed in an isotropic manner. Thereby, the T-shaped gate stack layer and the cavities are respectively formed. Hence, the dimension of the gate stack layer and the position of the cavities can be simultaneously monitored. In other words, the TFT of the present invention is satisfactorily reliable. Moreover, the additional ion implantation process and the complicated photomask process can be omitted in the present invention, and accordingly the manufacturing costs and the manufacturing time can both be reduced.

Through conducting the fabricating method of the TFT in the present invention, the dimension of the gate stack layer and the position of the cavities are apt to be adjusted. As such, determination of the height of the cavities by adjusting the height of the first conductive layer in the gate stack layer is further conducive to improvement of leakage current or enhancement of driving capacity of the TFT. Moreover, the length of the channel region of the TFT can be less than 3 microns in the present invention. As a result, the short channel effect issue in the TFT can be resolved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a poly-silicon island, comprising a source region and a drain region;
a gate insulating layer, covering the poly-silicon island;
a gate stack layer, disposed on the gate insulating layer, wherein the gate stack layer comprises a first conductive layer and a second conductive layer, and a length of the first conductive layer is less than a length of the second conductive layer; and
a dielectric layer, covering the gate insulating layer and the gate stack layer, a plurality of cavities being formed between the second conductive layer and the gate insulating layer.

2. The thin film transistor as claimed in claim 1, wherein the length of the second conductive layer is less than 3 microns.

3. The thin film transistor as claimed in claim 1, wherein a ratio of a distance between an edge of the first conductive layer and an edge of the second conductive layer to the length of the second conductive layer is less than 0.2.

4. The thin film transistor as claimed in claim 1, wherein a dielectric constant in the plurality of cavities is 1.

5. The thin film transistor as claimed in claim 1, wherein a material of the first conductive layer is selected from aluminum, indium tin oxide, or poly-germanium.

6. The thin film transistor as claimed in claim 1, wherein a material of the second conductive layer is selected from molybdenum or poly-silicon.

7. A fabricating method of a thin film transistor, comprising:
sequentially forming a poly-silicon island and a gate insulating layer on a substrate;
forming a gate stack layer on the gate insulating layer, the gate stack layer comprising a first conductive layer and a second conductive layer;
performing an etching process, wherein the etching process has an etching selectivity with respect to the first conductive layer and the second conductive layer, such that a length of the first conductive layer is less than a length of the second conductive layer, and a plurality of recesses are formed between the second conductive layer and the gate insulating layer;
forming a source region and a drain region in the poly-silicon island; and
forming a dielectric layer on the gate insulating layer, the dielectric layer covering the second conductive layer, wherein the plurality of recesses are not filled with the dielectric layer, and a plurality of cavities are formed between the second conductive layer and the gate insulating layer.

8. The fabricating method of the thin film transistor as claimed in claim 7, wherein an etching rate of the first conductive layer is at least twice an etching rate of the second conductive layer in the etching process.

9. The fabricating method of the thin film transistor as claimed in claim 7, wherein the length of the second conductive layer of the gate stack layer is less than 3 microns.

10. The fabricating method of the thin film transistor as claimed in claim 7, wherein a ratio of a distance between an edge of the first conductive layer and an edge of the second conductive layer to the length of the second conductive layer is less than 0.2.

11. The fabricating method of the thin film transistor as claimed in claim 7, wherein a method of forming the dielectric layer comprises performing a plasma enhanced chemical vapor deposition process or a sputtering process.

12. The fabricating method of the thin film transistor as claimed in claim 7, wherein a dielectric constant in the plurality of cavities is 1.

13. The fabricating method of the thin film transistor as claimed claim 7, wherein the etching process has a high etching selectivity ratio.

14. The fabricating method of the thin film transistor as claimed claim 13, wherein the etching process having the high etching selectivity ratio is performed with use of a wet etching solution.

15. The fabricating method of the thin film transistor as claimed claim 14, wherein the wet etching solution is selected from phosphoric acid, oxalic acid, or hydrogen peroxide.

16. The fabricating method of the thin film transistor as claimed claim 7, wherein a material of the first conductive layer is selected from aluminum, indium tin oxide, or poly-germanium.

17. The fabricating method of the thin film transistor as claimed in claim 7, wherein a material of the second conductive layer is selected from molybdenum or poly-silicon.
